(19) United States
(12) Patent Application Publication
(10) Pub. No.: US 2024/0370609 A1
(43) Pub. Date: Nov. 7, 2024

(54) SYSTEM AND METHOD FOR ACCIDENT RECONSTRUCTION

(71) Applicant: CCC INTELLIGENT SOLUTIONS INC., Chicago, IL (US)

(72) Inventors: Taha Khademinejad, Naperville, IL (US); Mahan Nia, Chicago, IL (US); Zia Ghiasi, Chicago, IL (US); Surendran Narayanamoorthy, Aurora, IL (US); Mohamad Reza Rooholamini, Chicago, IL (US)

(21) Appl. No.: 18/231,503

(22) Filed: Aug. 8, 2023

Related U.S. Application Data
(60) Provisional application No. 63/464,090, filed on May 4, 2023.

(51) Int. Cl. G06F 30/23

(52) U.S. Cl. CPC G06F 30/23

(57) ABSTRACT

A variety of algorithmic approaches such as Finite Element Modeling (FEM) and Surface Modeling (SM) use post-accident photos and other data to reconstruct an accident to improve vehicle damage and occupant injury determination. A database of vehicle models created with these techniques may then be used to create vehicle accident simulations and reconstruct the accident based on different impact and occupant parameters. Accident reconstruction using FEM and other techniques allows accident visualization for Auto Physical Damage (APD) corresponding to the vehicle's insurance policy, internal and external component damage prediction for the vehicle, and occupant injury prediction based on movement during the accident.

### CROSS-REFERENCE TO RELATED APPLICATIONS

This application claims the benefit of U.S. Provisional Patent Application Ser. No. 63/464,090 filed on May 4, 2023 and entitled “SYSTEM AND METHOD FOR ACCIDENT RECONSTRUCTION,” the entire disclosure of which is completely incorporated by reference herein.

### BACKGROUND

The background description provided herein is for the purpose of generally presenting the context of the disclosure. The work of the presently named inventors, to the extent it is described in this background section, as well as aspects of the description that may not otherwise qualify as prior art at the time of filing, are neither expressly nor impliedly admitted as prior art against the present disclosure.

At a high level, insurance companies have customers that are the subject of vehicle damage. The insurance company has numerous decisions to make including whether to try to fix the vehicle (or boat or motorcycle or other mobile device) or declare the vehicle “totaled” or a total loss and sell the vehicle for parts, if possible. In the past, a representative of the insurance company would have to physically view the wrecked vehicle and make an estimate of the cost to fix the vehicle and compare it to the value of the vehicle if it was declared a total loss.

As mobile phones such as smart phones have become more common and the images provided by mobile phones are improved, some insurance companies have tried to make the repair or total decision based solely on images of the damaged vehicle provided by the customers after the accident. However, the images are limited in their visual fidelity and the decision on whether to repair or total the vehicle can be challenging when the images miss key details or the details are blurry. Likewise, the images of vehicle body damage do not show damage to the vehicle's internal components or the injuries vehicle occupants might have received during the accident. Thus, there is a need to determine complete external and internal damage to the vehicle as well as occupant injuries based only on images and other information that are gathered after the accident has occurred.

### SUMMARY

The following presents a simplified summary of the present disclosure in order to provide a basic understanding of some aspects of the disclosure. This summary is not an extensive overview of the disclosure. It is not intended to identify key or critical elements of the disclosure or to delineate the scope of the disclosure. The following summary merely presents some concepts of the disclosure in a simplified form as a prelude to the more detailed description provided below.

The described system and method may take a plurality of post-accident photos and other data to reconstruct an accident. In some embodiments, the system and method may use a variety of algorithmic approaches such as Finite Element Modeling (FEM) and Surface Modeling (SM) based on post-accident photos and other data to create an analysis with improved results in a damage or injury determination. A database of vehicle models created with these techniques may then be used to create vehicle accident simulations and reconstruct the accident based on different impact parameters such as impact velocity, angle, offset, etc. The result of each simulation may provide: 1) accident visualization for Auto Physical Damage (APD) corresponding to the vehicle's insurance policy, 2) internal and external component damage prediction for the vehicle, and 3) occupant injury prediction based on movement during the accident.

In some embodiments, a computer-implemented method may reconstruct a vehicle accident to determine vehicle damage and occupant injury. The method may cause a processor to execute processor-executable instructions to define a plurality of points on a vehicle engineering drawing at each intersection of three or more vehicle components. The instructions may also cause the processor to divide each vehicle component into a plurality of elements. Each of the plurality of elements may include both local equations that describe degrees of freedom of the element and global equations that combine all local equations. The method may further cause the processor to add material properties and initial conditions for each vehicle component and solve the local equations and the general equations based on the material properties and initial conditions to generate accident simulation data. That accident simulation data may indicate deformation of one or more vehicle components. The method may also cause the processor to compile an accident damage report including all vehicle components that are indicated as deformed beyond a threshold.

In other embodiments, a processor and a memory may be in communication with the processor and the memory may store instructions that, when executed by the processor, cause the processor to reconstruct a vehicle accident to determine vehicle damage and occupant injury. Among others, the instructions may include: defining a plurality of points on a vehicle engineering drawing at each intersection of three or more vehicle components; dividing each vehicle component into a plurality of elements, wherein each of the plurality of elements includes both local equations that describe degrees of freedom of the element and global equations that combine all local equations; adding material properties and initial conditions for each vehicle component; solving the local equations and the general equations based on the material properties and initial conditions to generate accident simulation data, wherein the accident simulation data indicates deformation of one or more vehicle components; and compiling an accident damage report including all vehicle components that are indicated as deformed beyond a threshold.

The embodiments address the technical problems involved in analyzing external images using advanced computer systems and making predictions about internal and external vehicle damage as well as vehicle occupant injury.

### BRIEF DESCRIPTION OF THE FIGURES

The invention may be better understood by references to the detailed description when considered in connection with the accompanying drawings. The components in the figures are not necessarily to scale, emphasis instead being placed upon illustrating the principles of the invention. In the figures, like reference numerals designate corresponding parts throughout the different views.

FIG. 1 is an illustration of an exemplary accident reconstruction system;

FIG. 2 is an illustration of a flowchart including exemplary steps for the accident reconstruction system to reconstruct an accident;

FIG. 2A is an illustration of a neural network that may be employed within the accident reconstruction system;

FIG. 3 is an illustration of an exemplary computer-aided design drawing of a vehicle;

FIG. 4 is an illustration of an exemplary separated computer-aided design drawing of a vehicle;

FIG. 5 is an illustration of an exemplary separated computer-aided design drawing of a vehicle with internal and external components added;

FIG. 6 is an illustration of an exemplary separated and meshed computer-aided design drawing of a vehicle;

FIG. 7 is an illustration of an exemplary element of a finite element model including local equations;

FIG. 8 is an illustration of exemplary initial conditions for an accident reconstruction;

FIG. 9 is an illustration of an exemplary computing environment for the accident reconstruction system.

Persons of ordinary skill in the art will appreciate that elements in the figures are illustrated for simplicity and clarity so not all connections and options have been shown to avoid obscuring the inventive aspects. For example, common but well-understood elements that are useful or necessary in a commercially feasible embodiment are not often depicted in order to facilitate a less obstructed view of these various embodiments of the present disclosure. It will be further appreciated that certain actions and/or steps may be described or depicted in a particular order of occurrence while those skilled in the art will understand that such specificity with respect to sequence is not actually required. It will also be understood that the terms and expressions used herein are to be defined with respect to their corresponding respective areas of inquiry and study except where specific meaning have otherwise been set forth herein.

### SPECIFICATION

The present invention now will be described more fully hereinafter with reference to the accompanying drawings, which form a part hereof, and which show, by way of illustration, specific exemplary embodiments by which the invention may be practiced. These illustrations and exemplary embodiments are presented with the understanding that the present disclosure is an exemplification of the principles of one or more inventions and is not intended to limit any one of the inventions to the embodiments illustrated. The invention may be embodied in many different forms and should not be construed as limited to the embodiments set forth herein; rather, these embodiments are provided so that this disclosure will be thorough and complete, and will fully convey the scope of the invention to those skilled in the art. Among other things, the present invention may be embodied as methods or devices. Accordingly, the present invention may take the form of an entirely hardware embodiment, an entirely software embodiment or an embodiment combining software and hardware aspects. The following detailed description is, therefore, not to be taken in a limiting sense.

At a high level, insurance companies have customers that are the subject of vehicle damage from accidents and the like. After an accident involving a customer, the insurance company may have numerous decisions to make involving the vehicle and customer within the limits of the customer's insurance policy. Regarding the vehicle, the company may determine whether to fix the vehicle or declare the vehicle “totaled” or a total loss and sell the vehicle for parts, if possible. If there are bodily injuries, the company must determine which injuries are covered. All covered vehicle damage and personal injury must also result from the accident. These decisions are based on an understanding of both the internal and external damage to the vehicle and physical examination of any injuries. While physical inspection of the damaged vehicle may determine which vehicle components are damaged, this after-accident inspection may also identify components that were previously damaged or other damage that was not likely to have resulted from the accident in question. This analysis is also true for occupant injuries. After-the-fact damage or injury examinations may find issues that are not correlated to the accident. Physical inspection of the vehicle and injury examination may also be imperfect. Often, damage and injury may not be visible or may not be discoverable until much later when more significant problems arise. Causation determination only becomes more difficult with the passage of time. While photos or other after-the-fact data collected immediately after the accident may visually indicate damage and injury, analysis of these photos still requires expert, human intervention and analysis.

A method and system is described which attempts to address the technical problems involved in analyzing post-accident data to create an accident reconstruction. The accident reconstruction may then be used by various entities to estimate and/or determine the likelihood and severity of damage to individual vehicle components and occupant injury. A database of accident reconstructions may be based on different vehicles and impact parameters (e.g., velocity, angle, offset, etc.). Each accident reconstruction will provide visual confirmation of the accident for correlation to insurance coverages (i.e., Auto Physical Damage (APD)), and predict or confirm vehicle component internal and external damage, as well as occupant injuries. Using the database of accident reconstructions, prediction and/or confirmation of component damage and occupant injuries may be deterministic and/or probabilistic and may also include analysis by artificial intelligence methods to determine, predict, and/or confirm an accident reconstruction, vehicle component damage, and occupant injuries.

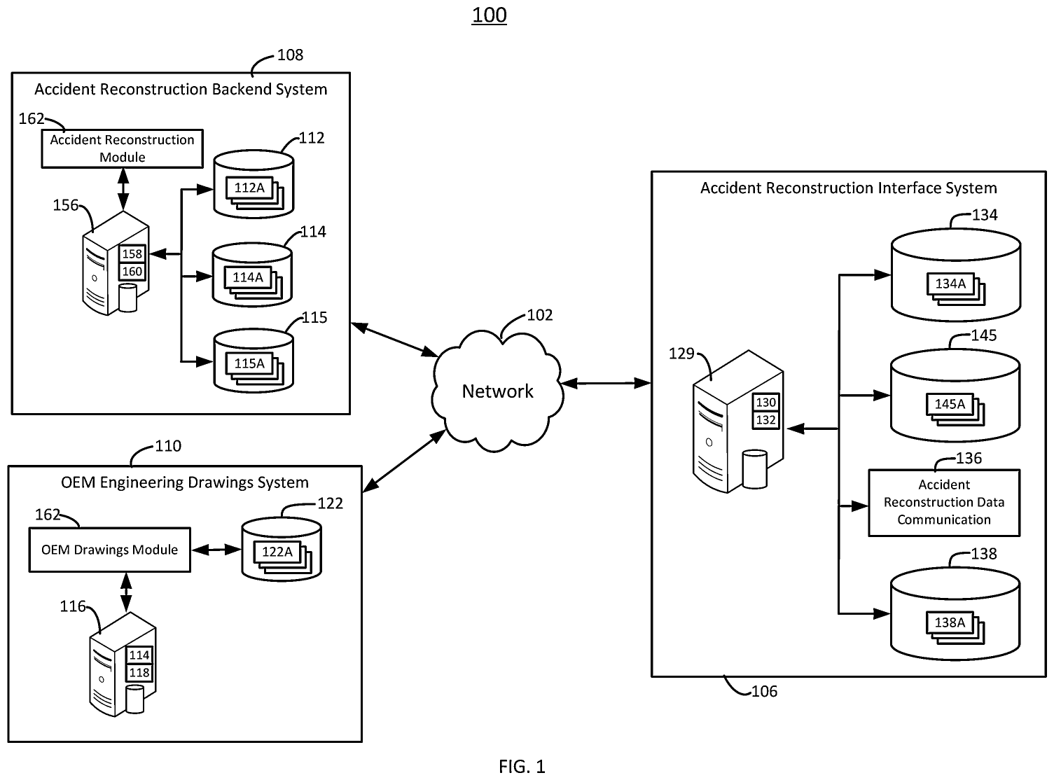

FIG. 1 generally illustrates one embodiment of an accident reconstruction system 100 for modeling vehicle accidents to visually confirm damage to various internal and external vehicle components, predict or confirm vehicle component internal and external damage, correlate component damage to Auto Physical Damage (APD) of a customer's insurance policy, and indicate possible occupant injuries. The system 100 may include a computer network 102 that links one or more systems and computer components. In some embodiments, the system 100 includes an accident reconstruction backend system 108, an accident reconstruction interface system 106, and an Original Equipment Manufacturer (OEM) engineering drawings system 110.

The network 102 may be described variously as a communication link, computer network, internet connection, etc. The system 100 may include various software or computer-executable instructions or components stored on tangible memories and specialized hardware components or modules that employ the software and instructions to determine an accident damage report 134A using various data related to past vehicle accidents and the present vehicle accident. For example, the system 100 may use accident simulation data 112A, vehicle data 114A, claim fulfillment data 115A, accident reconstruction data 145A from an accident reconstruction data repository 145, customer data profiles 138A, etc., to determine the report.

The various modules may be implemented as computer-readable storage memories containing computer-readable instructions (i.e., software) for execution by one or more processors of the system 100 within a specialized or unique computing device. The modules may perform the various tasks, methods, blocks, sub-modules, etc., as described herein. The system 100 may also include both hardware and software applications, as well as various data communications channels for communicating data between the various specialized and unique hardware and software components.

The network 102 includes the interconnection and interoperation of hardware, data, and other entities. The network 102, or data network, is a digital telecommunications network which allows nodes (e.g., accident reconstruction backend system 108, accident reconstruction interface system 106, and Original Equipment Manufacturer (OEM) engineering drawings system 110) to share resources. In computer networks, computing devices exchange data with each other using connections, i.e., data links, between nodes. Hardware networks, for example, may include clients, servers, and intermediary nodes in a graph topology. In a similar fashion, data networks may include data nodes in a graph topology where each node includes related or linked information, software methods, and other data. It should be noted that the term “server” as used throughout this application refers generally to a computer, other device, program, or combination thereof that processes and responds to the requests of remote users across a communications network. Servers serve their information to requesting “clients.” The term “client” as used herein refers generally to a computer, program, other device, user and/or combination thereof that is capable of processing and making requests and obtaining and processing any responses from servers across a communications or data network. A computer, other device, set of related data, program, or combination thereof that facilitates, processes information and requests, and/or furthers the passage of information from a source user to a destination user is commonly referred to as a “node.” Networks generally facilitate the transfer of information from source points to destinations. A node specifically tasked with furthering the passage of information from a source to a destination is commonly called a “router.” There are many forms of networks such as Local Area Networks (LANs), Pico networks, Wide Area Networks (WANs), Wireless Networks (WLANs), etc. For example, the Internet is generally accepted as being an interconnection of a multitude of networks whereby remote clients and servers may access and interoperate with one another.

The accident reconstruction interface system 106 may include a computing device such as an accident reconstruction interface server 129 including a processor 130 and memory 132. The system 106 may include components to facilitate accident reconstruction as herein described. In some embodiments, the accident reconstruction interface system 106 may also include an accident damage repository 134 storing one or more accident damage reports 134A that each indicate the most likely vehicle component damage and occupant injuries for a particular accident.

Each of the accident damage reports 134A may be created locally or remotely and include both vehicle damage and casualty. For example, the system 100 may determine vehicle damage and casualty for a present accident using accident simulation data 112A, vehicle data 114A, claim fulfillment data 115A, accident reconstruction data 145A from an accident reconstruction data repository 145, etc., to determine the report 134A. Claim fulfillment data 115A may indicate particular vehicle components and personal injuries that resulted from previous vehicle accidents. Similar accidents may include similar vehicle damage and casualty so that the system 100 may analyze past accident claim fulfillment data 115A to determine or predict particular vehicle components and personal injuries resulting from a present accident. Similarly, vehicle component damage may be determined by accident simulation data 112A from finite element modelling (FEM) of simulation vehicle data 114A, accident reconstruction data 145A. The system 100 may also determine casualty by executing processor-executable instructions to impose seat velocity data from the accident simulation data 112A to known sled test data from the OEM and occupant physical characteristics from the customer data profile 138A. The accident reconstruction data 145A may include accident characteristics that, when applied to accident simulation data 112A, determine an accident damage report 134A. For example, the accident reconstruction data 145A may include a speed and heading angle of the vehicle at the first contact, a type of obstacle or other obstacle characteristics, and the relative position and movement of the obstacle with respect to the vehicle. The accident reconstruction data 145A may also include data describing an initial velocity or velocity range of the vehicle, an angle range describing the angle of impact of the vehicle to an object, an offset range describing a portion of the vehicle that makes contact with the object and a portion that does not, a point of impact on the vehicle, a type of object the vehicle impacts, the type of model used for the occupant (e.g., a Total Human Model for Safety—THUMS—male model or other model to simulate human body kinematics and injury responses in car crashes), data describing the occupants (e.g., approximate age, sex, restraint information, previous known injuries, etc.), and seat belt, airbag, or other restraint data.

The accident reconstruction interface system 106 may receive the accident reconstruction data 145A directly or via the network 102 by telematics, first notice of loss (FNOL) data including an initial report made to an insurance provider following loss, theft, or damage of the vehicle, and photos of the vehicle or the accident scene. Some FNOL data may include the date, time, and location of the accident, a description of the vehicle damage, an initial value estimate of the damage, and witness data.

In some embodiments, the memory 132 may also include an accident reconstruction data communication module 136. The accident reconstruction data communication module 136 may include instructions to send and/or receive accident reconstruction data 145A, accident damage report data 134A, and other data to or from other components of the system 100 or components that are remote from the system 100.

The accident reconstruction interface system 106 may also include a customer data repository 138 including one or more customer data profiles 138A. Each customer data profile 138A may include data describing personal and insurance coverage characteristics of a customer. For example, the personal characteristics of a customer data profile 138A may include demographic and physical data for the customer that may influence injuries on the accident damage report 134A (e.g., height, weight, age, build, pre-existing physical limitations, etc.) and insurance policy limitations for casualty claims. The personal characteristics of the customer data profile 138A may also include one or more characteristics of a vehicle corresponding to the customer's insurance policy or Auto Physical Damage (APD). For example, the personal characteristics of the customer data profile 138A may include a year, make, and model of a vehicle that is covered by the APD constraints. Further personal characteristics of the customer data profile 138A may include a color, modifications to the vehicle as it was produced by the Original Equipment Manufacturer (i.e., deviations from typical factory production, etc.), customizations, etc. Insurance coverage characteristics of the customer data profile 138A may include the APD or other data describing compensation limitations for damage to the customer's vehicle caused by collision, theft, vandalism, fire, and other perils. For example, the APD may describe compensation the vehicle owner may receive for damage to the vehicle when it collides with another object, such as another car, a tree, or a building. This type of coverage typically has a deductible, which is the amount of money the customer is responsible for paying out of pocket for a covered loss. Comprehensive coverage may describe compensation the vehicle owner may receive for damage to the vehicle from other causes, such as fire, theft, vandalism, and failing objects. This type of coverage also typically has a deductible. Other types of data described by the APD may include excess collision coverage for damage that exceeds a collision deductible, comprehensive deductible waiver to release a vehicle owner from a comprehensive deductible if the vehicle is stolen, rental car reimbursement to pay for the cost of renting a car while the vehicle is being repaired or replaced, and towing and labor to pay for the cost of towing the vehicle to a repair shop and the labor costs associated with the repair.

The accident reconstruction backend system 108 may include an accident reconstruction server 156 including a processor 158 and memory 160. The memory 160 may include an accident reconstruction module 162 including processor-executable instructions to facilitate determining an accident damage report 134A using various remote or local data related to a vehicle accident. The accident reconstruction backend system 108 may also include an accident simulation data repository 112 storing accident simulation data 112A for a plurality of vehicles, a simulation vehicle data repository 114 storing simulation vehicle data 114A for the plurality of vehicles, and a claim fulfillment data repository 115 storing claim fulfillment data 115A for a plurality of accident claims. In some embodiments, the system 100 may use various data sources to determine the accident damage report 134A. For example, the system 100 may use accident simulation data 112A, vehicle data 114A, claim fulfillment data 115A, accident reconstruction data 145A from an accident reconstruction data repository 145, etc., to determine the report. Processor-executable instructions of the module 162 may also include instructions to cause the processor to process or modify data that is received at the accident reconstruction system 108 in response to a request via the network 102. The simulation vehicle data repository may include accident simulation data 112A that is incomplete for one or more vehicles. Using the various data sources described herein, the system 100 may execute processor-executable instructions to extrapolate the data for new parameters. For example, the system 100 may include simulation data for a vehicle speed of 30 and 35 miles-per-hour, but not for speeds between those values. Using AI/ML techniques, the system 100 may determine data for those missing values. Likewise, the accident reconstruction backend system 108 may be communicably connected to the OEM engineering drawings system 110 to receive vehicle data from the OEM to process or modify data that is received at the accident reconstruction backend system 108.

The system 110 may include an OEM engineering drawings server 116 including a processor 114 and memory 118. The memory 118 may include an OEM engineering drawings communication module 124 including processor-executable instructions to facilitate storing the engineering drawings 122A within the repository 122 and responding to requests from other subsystems (e.g., the accident reconstruction interface system 106, the accident reconstruction backend system 108, etc.) via the network 102 for one or more engineering drawings 122A.

Turning back to the accident reconstruction backend system 108, the memory 160 may include instructions that are executable by the processor 158 to send a request to the OEM engineering drawings system 110 for one or more engineering drawings 122A of a vehicle. The memory 160 of the accident reconstruction server 156 may include further instructions that are executable by the processor 158 to receive one or more engineering drawings 122A of a vehicle via the network 102 in response to the request. The memory 160 may include still further processor-executable instructions to modify a received engineering drawing 122A to facilitate determining an accident reconstruction report 134A. In some embodiments, modifying the received engineering drawing 122A may include processor-executable instructions for applying surface modelling techniques to the received engineering drawing 122A using a computer-aided design modeler (e.g., Solidworks®, SketchUp®, AutoCAD®, etc.).

Surface modeling is a type of 3D computer-aided design (CAD) that is used to create models of objects by defining the surfaces that make up the object. Surface models are created by specifying the shape, size, and location of each surface, as well as the relationships between the surfaces. Surface modeling is a more complex technique than wireframe modeling, but it offers a number of advantages. Surface models are more visually appealing than wireframe models, and they can be used to create more complex shapes. Surface models are also more accurate than wireframe models, because they can be used to define the exact shape and size of each surface.

The processor-executable instructions for modifying the received engineering drawing 122A by applying surface modelling techniques to the received engineering drawing 122A with the computer-aided design modeler may match lines with edges of the vehicle as shown in the engineering drawing 122A. The matched lines define various surfaces of the vehicle and vehicle body with the edges of the vehicle body. Processor-executable instructions to modify the received engineering drawing 122A to facilitate determining an accident reconstruction report 134A may also include adding other vehicle components to the drawings 122A using the computer-aided design modeler. For example, the instructions may include adding chassis and internal parts (e.g., engine, engine components and other driveline components, brakes, glass, fuel tank, vehicle batteries, wiring harnesses, etc.).

The instructions to apply surface modeling techniques may also include processor-executable instructions for separating and meshing the various surfaces of the vehicle and vehicle body as well as the added components. The processor-executable instructions for separating may include dividing the received engineering drawing into individual components. Separating may permit processing individual components of the model without affecting the rest of the model, improve the accuracy of the model, and make it easier to export the model to other software programs or subsystems of the accident reconstruction system 100. Meshing may include processor-executable instructions to divide a surface or volume of the received engineering drawing 122A, generally, and the separated components of the drawing 122A in particular, into a finite number of elements. This finite number of elements defines a mesh model of the vehicle or separated component. Generally, the mesh model is a type of 3D model that is made up of a network of interconnected points, lines, and faces. The processor-executable instructions for meshing may include surface meshing, volume meshing, or a combination of the two techniques. Processor-executable instructions for surface meshing may include dividing each of the defined surfaces of the vehicle drawing 122A into a finite number of elements to create a mesh model of each vehicle and component surface. Processor-executable instructions for volume meshing may include dividing a volume defined by several defined surfaces of the vehicle drawing into a finite number of elements to create a mesh model of various volumes of the vehicle and its components.

In addition to separating and meshing, the instructions to apply surface modeling techniques may also include processor-executable instructions for adding material properties to the mesh model. For example, surfaces and/or components made of steel or a type of plastic may have different deformation characteristics under physical stress. Thus, each element of the mesh model will include a local equation that is consistent with its shape and material properties to define that element's deformation and rigid body movement under different loads in an accident simulation.

Once the processor-executable instructions of the module 162 have modified the received engineering drawing 122A, further processor-executable instructions of the accident reconstruction module 162 may store the modified drawing as simulation vehicle data 114A within a simulation vehicle data repository 114.

The memory 160 may include further processor-executable instructions to determine accident simulation data 112A using finite element modeling (FEM). For example, the accident reconstruction module 162 may include further instructions to apply FEM to the simulation vehicle data 114A and the accident reconstruction data 145A to solve local and global equations. The accident reconstruction data 145A includes accident characteristics that, when applied to accident simulation data 112A, determine an accident damage report 134A. For example, the accident reconstruction data 145A may include a speed and heading angle of the vehicle at the first contact, a type of obstacle or other obstacle characteristics, and the relative position and movement of the obstacle with respect to the vehicle. As briefly described above, each element of the separated and meshed simulation vehicle data 114A has a local equation to define its deformation and rigid body movement under accident load that is based on that element's shape and material. Each element's local equation includes six degrees of freedom (DOF) that refer to the number of independent variables that are used to describe the deformation of the element. These six DOF are translation in the x, y, and z-directions and rotation in the x, y, and z-directions. Each node in the simulation vehicle data 114A mesh has six DOF. A node in the simulation vehicle data 114A is a point in space where the displacement, stress, and strain are defined. Nodes are connected to each other by elements, which are the building blocks of the simulation vehicle data 114A mesh. Six DOF means that each node can move in any direction and rotate about any axis. In some embodiments, the DOF at each node define local equations for each element of the simulation vehicle data 114A that are combined by a global equation to calculate the deformation of the vehicle and its various components.

The memory 160 may include further processor-executable instructions to add a vehicle surface and/or component to the accident damage report when the simulation of the accident using finite element modeling (FEM) indicates deformation of one or more elements of the simulation vehicle data 114A beyond a threshold. The threshold may indicate whether the surface or component of the vehicle simulation data 114A is damaged for inclusion in an accident damage report 134A for the accident. The threshold may correspond to an amount of deformation for one or more elements of the vehicle surface or component, or may correspond to an amount of elements that include any deformation for the vehicle surface or component. For example, solving the local and global equations upon application of the accident reconstruction data 145A to the simulation vehicle data may indicate deformation of elements that comprise the surfaces and components of the vehicle in the simulation vehicle data 114A. Deformation of an element beyond a threshold deformation amount may indicate that the vehicle surface or component including that element is damaged. In other embodiments, any deformation of a number of elements beyond a threshold number of elements may indicate that the surface or component including that element is damaged. If one or more of the thresholds is exceeded, then the further processor-executable instructions may add the damaged surface and/or component to the accident damage report 134A.

The memory 160 may also include processor-executable instructions to determine occupant injuries caused by the accident. In some embodiments, the processor-executable instructions include retrieving sled test data as part of the received engineering drawing data 122A. Sled test data may be compiled by the OEM along with a human body model to determine the injuries that occupants in vehicle accidents may sustain. The data is collected from crash tests in which a vehicle is towed by a sled and then crashed into a barrier. The sled is equipped with sensors that measure the forces and accelerations that are experienced by the vehicle and its occupants during the crash. This data can then be used to create mathematical models that can predict the likelihood of injury for different types of crashes. In some embodiments, the processor-executable instructions impose seat velocity data from the accident simulation data 112A to the sled test data from the OEM as well as occupant physical characteristics from the customer data profile 138A and occupant positions or other considerations for the particular accident indicated by the accident reconstruction data 145A. In some embodiments, the accident reconstruction data 145A includes accident characteristics that, when applied to accident simulation data 112A, determine an accident damage report 134A. For example, the accident reconstruction data 145A may include airbag deployment data, seatbelt fastened data, vehicle speed or change in velocity data, and out-of-position seating data (e.g., normal, close to wheel, extended arm, reaching down, etc.). Other accident reconstruction data 145A used to determine occupant injury may include objects inside the vehicle data (e.g., cell phone on dashboard, unsecured cargo, etc.) that may become injury-causing projectiles during an accident.

The memory 160 may also include processor-executable instructions to determine the accident damage report 134A according to limits of the customer's vehicle and casualty insurance policies to indicate what vehicle components and injuries are covered.

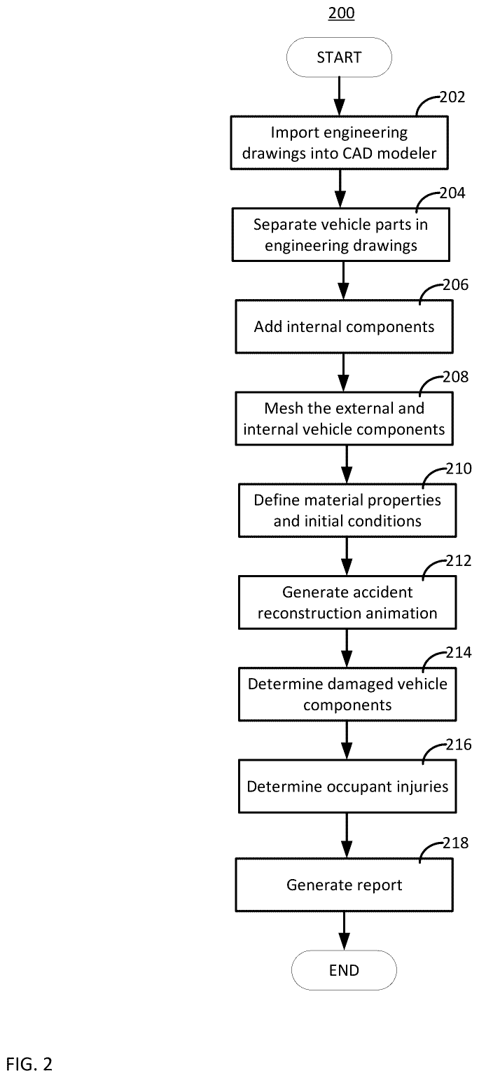

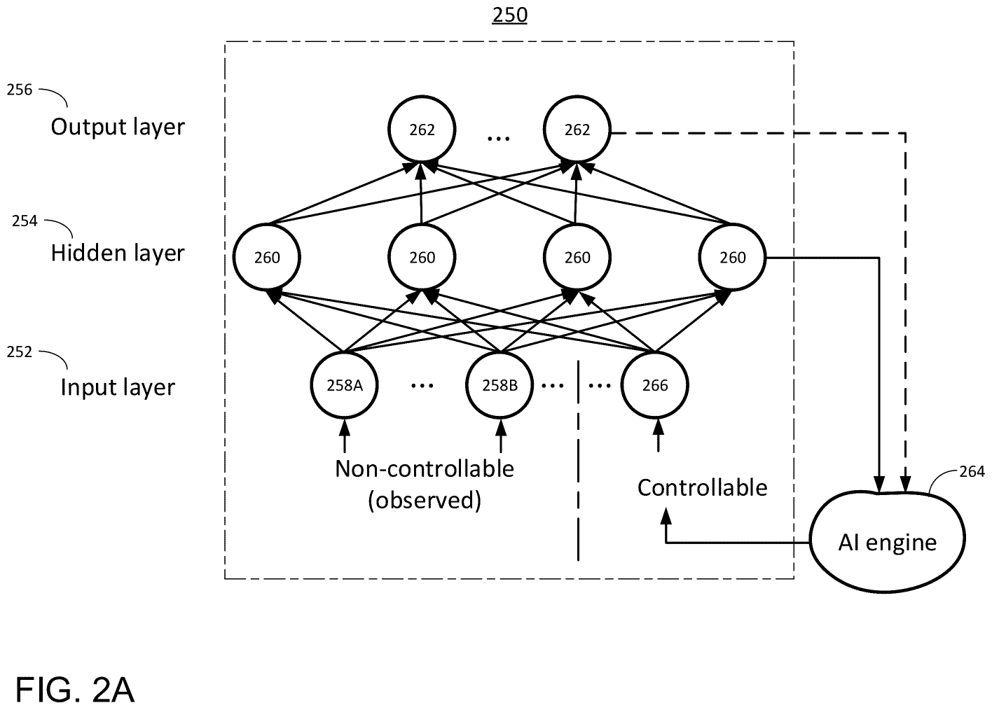

With reference to FIG. 2, a flowchart of a method 200 for reconstructing an accident by analyzing post-accident data to create a simulation of the accident which is then used to determine vehicle damage and casualty loss corresponding to the accident. Each step of the method 200 is one or more processor-executable instructions performed on a server or other computing device which may be physically configured to execute the different aspects of the method. Each step may include execution of any of the instructions as described in relation to the system 100. While the below blocks are presented as an ordered set, the various steps described may be executed in any particular order to complete the accident reconstruction methods described herein.

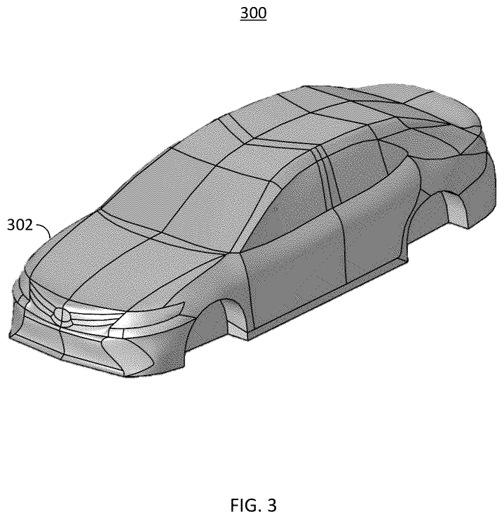

At block 202, the method 200 may execute instructions to cause a processor of the system 100 to import one or more engineering drawings 122A of a vehicle involved in an accident from the OEM engineering drawings server via the network 102. In some embodiments, the method 200 may import the one or more engineering drawings 122A into CAD modeler software such as Solidworks® or a similar CAD editing system. With reference to FIG. 3, the engineering drawings 122A may include a CAD drawing 300 including at least an external portion 302 of the vehicle.

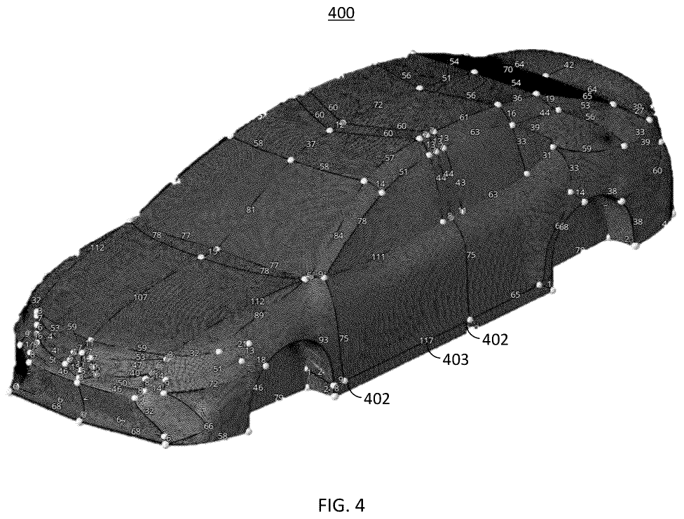

At block 204, the method 200 may execute instructions to cause a processor of the system 100 to separate and mesh the CAD drawing 300. With reference to FIG. 4, in some embodiments, the instructions create a separated CAD drawing 400 may include defining points 402 for each intersection of parts (e.g., surface panels or interior parts). For example, the method 200 may define a plurality of points on the CAD drawing 300 at each intersection of three or more vehicle components.

A line between the points 402 may define an edge 403 of the CAD drawing. Each edge 403 may then be used in a finite element model of the vehicle to visualize the results of finite element analysis and to identify areas of high stress on the vehicle during the accident. The edges 403 may be numbered for identification of stress contours and points of impact for the accident reconstruction. In some embodiments, the method 200 may match lines with edges of the vehicle as shown in the engineering drawing CAD drawing 300. The matched lines define various surfaces of the vehicle and vehicle body with the edges of the vehicle body. In further embodiments, the method 200 may execute instructions to perform a convolution operation on the CAD drawing 300 to extract the high-level features such as edges 403, from the input image.

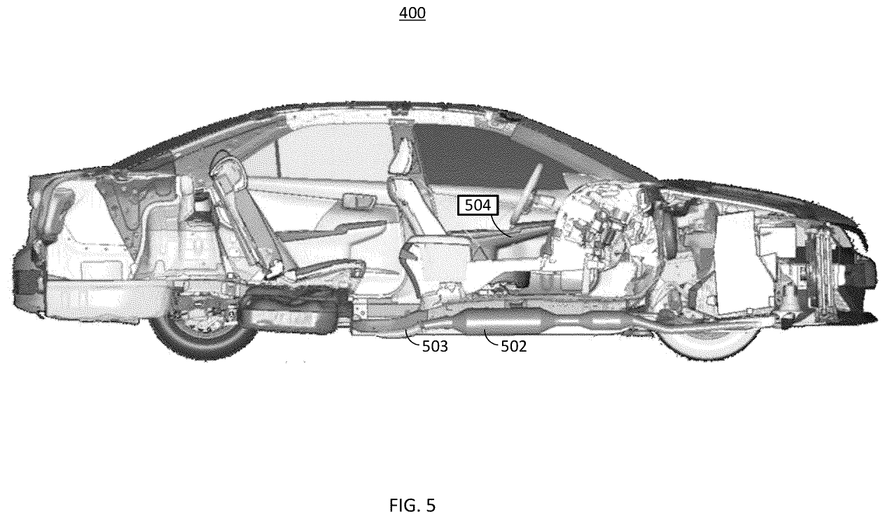

At block 206, the method 200 may execute instructions to cause a processor of the system 200 to modify the separated CAD drawing 400 by adding other vehicle components to the drawing 300 using a computer-aided design modeler. With reference to FIG. 5, for example, the instructions may include adding chassis and internal parts (e.g., engine, engine components and other driveline components, brakes, glass, fuel tank, vehicle batteries, wiring harnesses, etc.) such as 502, 503, and 504, etc.

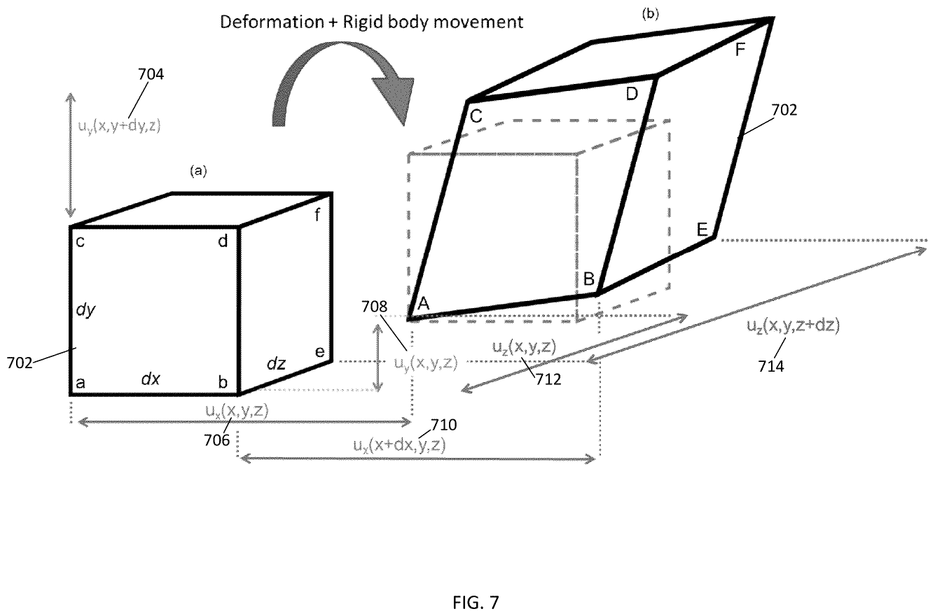

At block 208, the method 200 may execute instructions to cause a processor of the system 200 to mesh the external and internal parts of the separated CAD drawing 400. In some embodiments, the instructions may divide the geometry of the separated CAD drawing 400 into very small pieces or elements (e.g., 602, 603, 604, etc.). Further instructions may cause the processor to define a local equation for each element of the mesh. With reference to FIG. 7, deformation of a single element 702 may be described by a plurality of equations (e.g., equations 704, 706, 708, 710, 712, 714). The plurality of equations may describe degrees of freedom of the element. In some embodiments, the local equations 704, 706, 708, 710, 712, 714 describe translation in the x, y, and z-directions and rotation in the x, y, and z-directions. During accident reconstructions, a global equation may then combine all local equations to be solved to determine deformation of the external and internal parts of the separated CAD drawing 400.

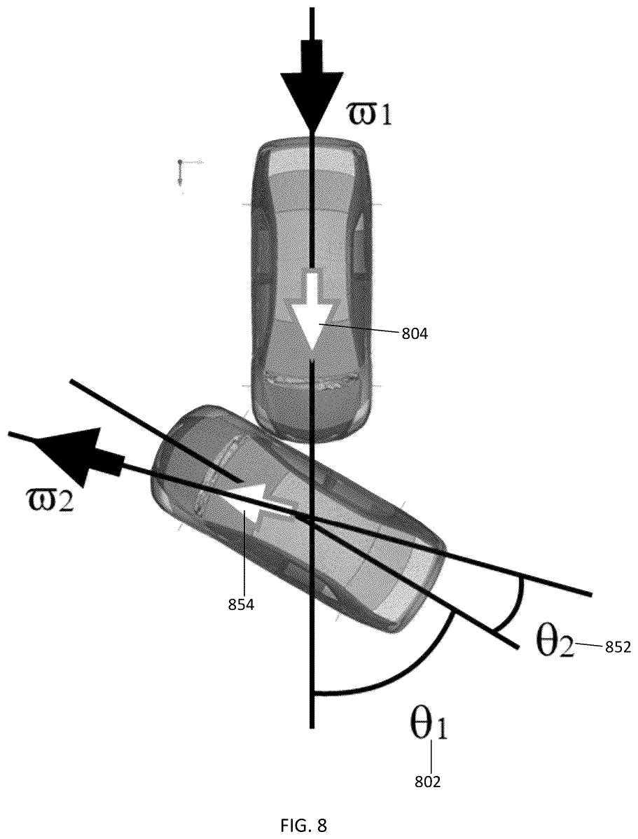

At block 210, the method 200 may execute instructions to cause a processor of the system 200 to define material properties and initial conditions of the vehicle accident reconstruction. With reference to FIG. 8, initial conditions may include one or more of a heading angle (802, 852), a direction of travel (804, 854), an impact speed, relative position of the vehicle to an obstacle (e.g., another vehicle or other object), occupants, and pedestrians. The instructions may also add material properties for each component or element of the separated CAD drawing 400. For example, surfaces and/or components of the vehicle made of steel or a type of plastic may have different deformation characteristics under physical stress.

At block 212, the method 200 may execute instructions to cause a processor of the system 200 to generate an accident reconstruction animation or accident simulation data 112A. In some embodiments, a two-dimensional plot or three-dimensional animation may allow analysis of various characteristics of the accident including: speed over time, displacement or deformation of various vehicle components over time, a von Mises yield criterion to show when each of the various vehicle components will yield or fail during the accident, a probabilistic and/or deterministic artificial intelligence analysis, a regression analysis, and other analyses. Using the material properties and initial conditions that were defined at block 210, and the meshed external and internal vehicle components of block 208 (i.e., the separated and meshed simulation vehicle data 114A), the method 200 may solve all local equations and combine them with a global solution to calculate the deformation of the vehicle and its various components.

At block 214, the method 200 may execute instructions to cause a processor of the system 200 to determine one or more damaged vehicle components. As described above in relation to the accident reconstruction module 162, when the simulation of the accident at block 212 indicates deformation of one or more elements of the simulation vehicle data 114A beyond a threshold or indicates a number of deformed elements that are beyond a threshold, a surface or component of the vehicle is damaged. If one or more of the thresholds is exceeded, then the further processor-executable instructions may add the damaged surface and/or component to the accident damage report 134A. As with the instructions at block 212, the instructions at block 214 may also determine one or more damaged vehicle components and physical injuries from the accident using a probabilistic and/or deterministic artificial intelligence analysis.

With reference to FIG. 2A, processor-executable instructions of the module 162 may also include instructions for a machine learning (ML) architecture 250 (e.g., a neural network) that is used with the system 100 in accordance with the current disclosure. In some embodiments, the module 162 may include instructions for execution on one or more processors that implement the ML architecture 250. The ML architecture 250 may include an input layer 252, a hidden layer 254, and an output layer 256. The input layer 252 may include inputs 258A, 258B, etc., coupled to other subsystems or elements of the system 100 (e.g., the accident reconstruction interface system 106, the OEM engineering drawings system 110, etc.) and represent those inputs that are observed from actual system data, such as the accident simulation data 112A, simulation vehicle data 114A, accident damage reports 134A, customer data profiles 138A, accident reconstruction data 145A, etc.

The hidden layer 254 may include weighted nodes 260 that have been trained for the observed inputs. Each node 260 of the hidden layer 254 may receive the sum of all inputs 258A, 258B, etc., multiplied by a corresponding weight. The output layer 256 may present various outcomes 262 based on the input values 258A, 258B, etc., and the weighting of the hidden layer 254. Just as a machine learning system for a self-driving car may be trained to determine hazard avoidance actions based on received visual input, the machine learning architecture 250 may be trained to analyze a likely outcome for a given set of inputs based on thousands or even millions of observations of previous accidents, vehicles, occupants, etc. For example, the architecture 250 may be trained to determine the damaged vehicle components and occupant injuries based on the accident reconstruction for an accident damage report 134A as described herein.

During training of the machine learning architecture 250, a dataset of inputs may be applied and the weights of the hidden layer 260 may be adjusted for the known outcome (e.g., observed component damage and occupant injuries) associated with that dataset. As more datasets are applied, the weighting accuracy may improve so that the outcome prediction is constantly refined to a more accurate result. In this case, the accident reconstruction interface system 106 and the OEM engineering drawings system 110 may provide datasets for initial training and ongoing refining of the machine learning architecture 250.

Additional training of the machine learning architecture 250 may include the an artificial intelligence engine (AI engine) 264 providing additional values to one or more controllable inputs 266 so that outcomes may be observed for particular changes to the observed data. The values selected may represent different data types such as a frequency of observed ranges of input layer data, a frequency with which particular component damage or occupant injuries occur, and other alternative data observed from an accident and may be generated at random or by a pseudo-random process. By adding controlled variables to the input layer data, the impact may be measured and fed back into the machine learning architecture 250 weighting to allow capture of an impact on a proposed change to the accident reconstruction in order to optimize precise prediction of vehicle component damage and occupant injury. Over time, the impact of various different data at different points in the accident may be used to predict an outcome for a given set of observed values at the inputs layer 252.

After training of the machine learning architecture 250 is completed, data from the hidden layer 254 may be fed to the artificial intelligence engine 264 to generate values for controllable input(s) 266 to optimize the deterministic, predictive, and/or probabilistic capabilities of the system 100 for vehicle component damage and physical injuries to persons involved in the accident. Similarly, data from the output layer may be fed back into the artificial intelligence engine 264 so that the artificial intelligence engine 264 may, in some embodiments, iterate with different data to determine, via the trained machine learning architecture 250, whether the data received from the accident reconstruction interface system 106 and/or the OEM engineering drawings system 110 is accurate, and other determinations.

The instructions at blocks 212 and 214 may also determine one or more damaged vehicle components and physical injuries from an accident using a regression analysis. In some embodiments, the system 100 may employ one or more machine learning algorithms, such as linear regression, polynomial regression, logistic regression, decision trees, random forests, and support vector machines to determine one or more damaged vehicle components and physical injuries from the accident. These algorithms may help the system 100 learn from the various data sources and optimize their parameters to find the best-fitting function that represents the relationship between variables to determine an accident damage report 134A.

At block 216, the method may execute instructions to cause a processor of the system 200 to determine one or more occupant injuries. In some embodiments, the instructions impose seat velocity data from the accident simulation data 112A to the sled test data from the OEM as well as occupant physical characteristics from the customer data profile 138A and occupant positions or other considerations for the particular accident indicated by the accident reconstruction data 145A. As with the instructions at blocks 212 and 214, the instructions at block 216 may also determine one or more occupant injuries using a probabilistic and/or deterministic artificial intelligence analysis.

At block 218, the method may execute instructions to cause a processor of the system 200 to compile the accident damage report 134A for the damaged vehicle components and occupant injuries based on the accident reconstruction. Because the simulation accounts for the interaction of all vehicle surfaces and components during the accident, damage that cannot be seen by the typical estimate process may be accounted for.

Using a variety of algorithmic approaches such as Finite Element Modeling (FEM) and Surface Modeling (SM) based on post-accident photos and other data, the systems and methods described herein create an accident analysis that improves damage and injury determination. A database of vehicle models created with these techniques may then be used to create vehicle accident simulations and reconstruct the accident based on different impact parameters. Accident reconstruction using FEM and other techniques allows accident visualization for Auto Physical Damage (APD) corresponding to the vehicle's insurance policy, internal and external component damage prediction for the vehicle, and occupant injury prediction based on movement during the accident.

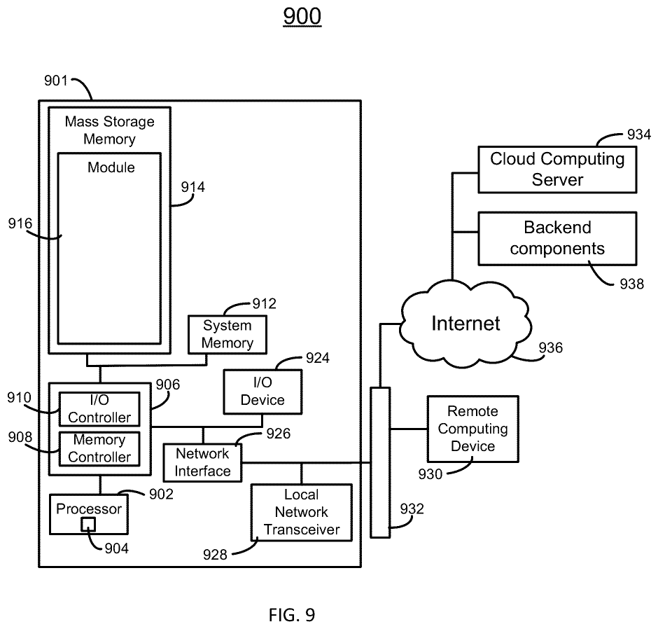

As shown in FIG. 9, the computing device 901 (i.e., servers 116, 129, and 156 of FIG. 1) includes a processor 902 that is coupled to an interconnection bus. The processor 902 includes a register set or register space 904, which is depicted in FIG. 9 as being entirely on-chip, but which could alternatively be located entirely or partially off-chip and directly coupled to the processor 902 via dedicated electrical connections and/or via the interconnection bus. The processor 902 may be any suitable processor, processing unit or microprocessor. Although not shown in FIG. 9, the computing device 901 may be a multi-processor device and, thus, may include one or more additional processors that are identical or similar to the processor 902 and that are communicatively coupled to the interconnection bus.

The processor 902 of FIG. 9 is coupled to a chipset 906, which includes a memory controller 908 and a peripheral input/output (1/O) controller 910. As is well known, a chipset typically provides I/O and memory management functions as well as a plurality of general purpose and/or special purpose registers, timers, etc. that are accessible or used by one or more processors coupled to the chipset 906. The memory controller 908 performs functions that enable the processor 902 (or processors if there are multiple processors) to access a system memory 912 and a mass storage memory 914, that may include either or both of an in-memory cache (e.g., a cache within the memory 912) or an on-disk cache (e.g., a cache within the mass storage memory 914).

The system memory 912 may include any desired type of volatile and/or non-volatile memory such as, for example, static random access memory (SRAM), dynamic random access memory (DRAM), flash memory, read-only memory (ROM), etc. The mass storage memory 914 may include any desired type of mass storage device. For example, the computing device 901 may be used to implement a module 916 (e.g., the various modules as described in relation to FIG. 1). The mass storage memory 914 may include a hard disk drive, an optical drive, a tape storage device, a solid-state memory (e.g., a flash memory, a RAM memory, etc.), a magnetic memory (e.g., a hard drive), or any other memory suitable for mass storage. As used herein, the terms module, block, function, operation, procedure, routine, step, and method refer to tangible computer program logic or tangible computer executable instructions that provide the specified functionality to the computing device 901, the systems and methods described herein. Thus, a module, block, function, operation, procedure, routine, step, and method can be implemented in hardware, firmware, and/or software. In one embodiment, program modules and routines are stored in mass storage memory 914, loaded into system memory 912, and executed by a processor 902 or can be provided from computer program products that are stored in tangible computer-readable storage mediums (e.g. RAM, hard disk, optical/magnetic media, etc.).

The peripheral I/O controller 910 performs functions that enable the processor 902 to communicate with a peripheral input/output (1/O) device 924, a network interface 926, a local network transceiver 928, (via the network interface 926) via a peripheral I/O bus. The I/O device 924 may be any desired type of I/O device such as, for example, a keyboard, a display (e.g., a liquid crystal display (LCD), a cathode ray tube (CRT) display, etc.), a navigation device (e.g., a mouse, a trackball, a capacitive touch pad, a joystick, etc.), etc. The I/O device 924 may be used with the module 916, etc., to receive data from the transceiver 928, send the data to the components of the system 100, and perform any operations related to the methods as described herein. The local network transceiver 928 may include support for a Wi-Fi network, Bluetooth, Infrared, cellular, or other wireless data transmission protocols. In other embodiments, one element may simultaneously support each of the various wireless protocols employed by the computing device 901. For example, a software-defined radio may be able to support multiple protocols via downloadable instructions. In operation, the computing device 901 may be able to periodically poll for visible wireless network transmitters (both cellular and local network) on a periodic basis. Such polling may be possible even while normal wireless traffic is being supported on the computing device 901. The network interface 926 may be, for example, an Ethernet device, an asynchronous transfer mode (ATM) device, an 802.11 wireless interface device, a DSL modem, a cable modem, a cellular modem, etc., that enables the system 100 to communicate with another computer system having at least the elements described in relation to the system 100.

While the memory controller 908 and the I/O controller 910 are depicted in FIG. 9 as separate functional blocks within the chipset 906, the functions performed by these blocks may be integrated within a single integrated circuit or may be implemented using two or more separate integrated circuits. The computing environment 900 may also implement the module 916 on a remote computing device 930. The remote computing device 930 may communicate with the computing device 901 over an Ethernet link 932. In some embodiments, the module 916 may be retrieved by the computing device 901 from a cloud computing server 934 via the Internet 936. When using the cloud computing server 934, the retrieved module 916 may be programmatically linked with the computing device 901. The module 916 may be a collection of various software platforms including artificial intelligence software and document creation software or may also be a Java® applet executing within a Java® Virtual Machine (JVM) environment resident in the computing device 901 or the remote computing device 930. The module 916 may also be a “plug-in” adapted to execute in a web-browser located on the computing devices 901 and 930. In some embodiments, the module 916 may communicate with back end components 938 via the Internet 936.

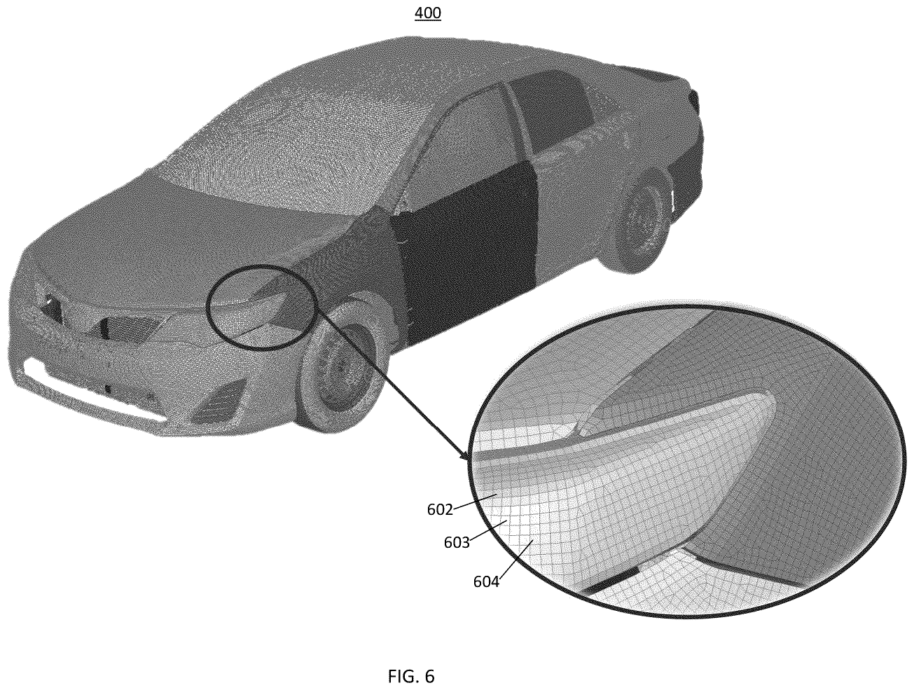

The system 900 may include but is not limited to any combination of a LAN, a MAN, a WAN, a mobile, a wired or wireless network, a private network, or a virtual private network. Moreover, while only one remote computing device 930 is illustrated in FIG. 6 to simplify and clarify the description, it is understood that any number of client computers are supported and can be in communication within the system 900.

Additionally, certain embodiments are described herein as including logic or a number of components, modules, or mechanisms. Modules may constitute either software modules (e.g., code or instructions embodied on a machine-readable medium wherein the code is executed by a processor) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. As used herein, “hardware-implemented module” refers to a hardware module. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

The one or more processors may also operate to support performance of the relevant operations in a “cloud computing” environment or as a “software as a service” (SaaS). For example, at least some of the operations may be performed by a group of computers (as examples of machines including processors), these operations being accessible via a network (e.g., the Internet) and via one or more appropriate interfaces (e.g., application program interfaces (APIs).)

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “some embodiments” or “an embodiment” or “teaching” means that a particular element, feature, structure, or characteristic described in connection with the embodiment is included in at least one embodiment. The appearances of the phrase “in some embodiments” or “teachings” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

Further, the figures depict preferred embodiments for purposes of illustration only. One skilled in the art will readily recognize from the following discussion that alternative embodiments of the structures and methods illustrated herein may be employed without departing from the principles described herein

Upon reading this disclosure, those of skill in the art will appreciate still additional alternative structural and functional designs for the systems and methods described herein through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the systems and methods disclosed herein without departing from the spirit and scope defined in any appended claims.

1. A computer-implemented method of reconstructing a vehicle accident to determine vehicle damage and occupant injury, the method comprising:
defining a plurality of points on a vehicle engineering drawing at each intersection of three or more vehicle components;
dividing each vehicle component into a plurality of elements, wherein each of the plurality of elements includes both local equations that describe degrees of freedom of the element and global equations that combine all local equations;
adding material properties and initial conditions for each vehicle component;
solving the local equations and the general equations based on the material properties and initial conditions to generate accident simulation data, wherein the accident simulation data indicates deformation of one or more vehicle components; and
compiling an accident damage report including all vehicle components that are indicated as deformed beyond a threshold.

2. The computer-implemented method of claim 1, further comprising importing the vehicle engineering drawing from an original equipment manufacturer engineering drawings system to a computer-aided design modeler.

3. The computer-implemented method of claim 1, wherein the vehicle components include external vehicle panels and internal vehicle parts.

4. The computer-implemented method of claim 1, further comprising identifying a component edge between each pair of points of the plurality of points.

5. The computer-implemented method of claim 4, further comprising identifying one or more areas of high stress on the vehicle based on the component edge.

6. The computer-implemented method of claim 1, wherein the local equations define six degrees of freedom for each corresponding element.

7. The computer-implemented method of claim 6, wherein the six degrees of freedom define, for each of the plurality of elements, translation in the x, y, and z-directions and rotation in the x, y, and z-directions.

8. The computer-implemented method of claim 1, wherein the initial conditions include one or more of a heading angle, a direction of travel, an impact speed, a relative position of the vehicle to the obstacle, occupant characteristics, and pedestrian characteristics.

9. The computer-implemented method of claim 8, further comprising determining one or more occupant injuries based on the initial conditions.

10. The computer-implemented method of claim 9, wherein determining one or more occupant injuries based on the initial conditions includes imposing seat velocity data from the initial conditions, occupant physical characteristics, and occupant positions to sled test data from an OEM.

11. A system comprising:
a processor and a memory in communication with the processor, the memory storing instructions that, when executed by the processor, cause the processor to:
define a plurality of points on a vehicle engineering drawing at each intersection of three or more vehicle components;
divide each vehicle component into a plurality of elements, wherein each of the plurality of elements includes both local equations that describe degrees of freedom of the element and global equations that combine all local equations;
add material properties and initial conditions for each vehicle component;
solve the local equations and the general equations based on the material properties and initial conditions to generate accident simulation data, wherein the accident simulation data indicates deformation of one or more vehicle components; and
compile an accident damage report including all vehicle components that are indicated as deformed beyond a threshold.

12. The system of claim 11, further comprising instructions that, when executed by the processor, cause the processor to import the vehicle engineering drawing from an original equipment manufacturer engineering drawings system to a computer-aided design modeler.

13. The system of claim 11, wherein the vehicle components include external vehicle panels and internal vehicle parts.

14. The system of claim 11, further comprising instructions that, when executed by the processor, cause the processor to identify a component edge between each pair of points of the plurality of points.

15. The system of claim 14, further comprising instructions that, when executed by the processor, cause the processor to identify one or more areas of high stress on the vehicle based on the component edge.

16. The system of claim 11, wherein the local equations define six degrees of freedom for each corresponding element.

17. The system of claim 16, wherein the six degrees of freedom define, for each of the plurality of elements, translation in the x, y, and z-directions and rotation in the x, y, and z-directions.

18. The system of claim 11, wherein the initial conditions include one or more of a heading angle, a direction of travel, an impact speed, a relative position of the vehicle to the obstacle, occupant characteristics, and pedestrian characteristics.

19. The system of claim 18, further comprising instructions that, when executed by the processor, cause the processor to determine one or more occupant injuries based on the initial conditions.

20. The system of claim 19, wherein the instructions that, when executed by the processor, cause the processor to determine one or more occupant injuries based on the initial conditions include instructions that, when executed by the processor, cause the processor to impose seat velocity data from the initial conditions, occupant physical characteristics, and occupant positions to sled test data from an OEM.
